(19) United States
(12) Patent Application Publication
(10) Pub. No.: US 2026/0060142 A1
(43) Pub. Date: Feb. 26, 2026

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: JUNGHOON KANG, Suwon-si (KR); JIHYE SHIM, Suwon-si (KR)

(21) Appl. No.: 19/061,756

(22) Filed: Feb. 24, 2025

(30) Foreign Application Priority Data
Aug. 20, 2024 (KR) 10-2024-0111467

(51) Int. Cl. H01L 25/16; H01L 23/00; H01L 23/31; H01L 23/48; H10B 80/00; H10D 80/30

(52) U.S. Cl. CPC H01L 25/16; H01L 23/3185; H01L 23/481; H01L 24/05; H01L 24/06; H01L 24/32; H10B 80/00; H10D 80/30; H01L 24/13; H01L 24/16; H01L 24/73; H01L 24/96; H01L 24/97; H01L 2224/05554; H01L 2224/0603; H01L 2224/06135; H01L 2224/13111; H01L 2224/13139; H01L 2224/16145; H01L 2224/32014; H01L 2224/32145; H01L 2224/73; H01L 2224/96; H01L 2224/97; H01L 2225/06513; H01L 2225/06544; H01L 2924/37001

(57) ABSTRACT

Disclosed are semiconductor packages and their fabricating methods. A semiconductor package includes a first semiconductor die, a second semiconductor die on the first semiconductor die, an underfill layer between the first semiconductor die and the second semiconductor die, and a mold layer on a top surface of the first semiconductor die and a lateral surface of the second semiconductor die. The first semiconductor die includes a first semiconductor substrate and an edge conductive pad on a rear surface of the first semiconductor substrate. One portion of the edge conductive pad overlaps the second semiconductor die. Another portion of the edge conductive pad is covered with the mold layer.

### CROSS-REFERENCE TO RELATED APPLICATIONS

This application claims priority under 35 U.S.C § 119 to Korean Patent Application No. 10-2024-011467 filed on Aug. 20, 2024 in the Korean Intellectual Property Office, the disclosure of which is hereby incorporated by reference in its entirety.

### BACKGROUND

The present inventive concepts relate to a semiconductor package and a method of fabricating the same.

A semiconductor package is provided to implement an integrated circuit chip to qualify for use in electronic products. A semiconductor package is typically configured such that a semiconductor die is mounted on a printed circuit board (PCB) and bonding wires or bumps are used to electrically connect the semiconductor die to the printed circuit board. With the development of electronic industry, many studies have been conducted to improve reliability and durability of semiconductor packages.

### SUMMARY OF THE INVENTION

Some embodiments of the present inventive concepts provide a semiconductor package with improved reliability.

Some embodiments of the present inventive concepts provide a method of fabricating a semiconductor package, which method is capable of increasing a yield.

The object of the present inventive concepts is not limited to the mentioned above, and other objects which have not been mentioned above will be clearly understood to those skilled in the art from the following description.

According to some embodiments of the present inventive concepts, a semiconductor package may include a first semiconductor die; a second semiconductor die on the first semiconductor die; an underfill layer between the first semiconductor die and the second semiconductor die; and a mold layer on a top surface of the first semiconductor die and a lateral surface of the second semiconductor die. The first semiconductor die may include a first semiconductor substrate; and an edge conductive pad on a rear surface of the first semiconductor substrate. One portion of the edge conductive pad and the second semiconductor die may overlap. Another portion of the edge conductive pad may be covered by the mold layer.

According to some embodiments of the present inventive concepts, a semiconductor package may include a first semiconductor die; a second semiconductor die on the first semiconductor die; an underfill layer between the first semiconductor die and the second semiconductor die; and a mold layer on a top surface of the first semiconductor die and a lateral surface of the second semiconductor die. The first semiconductor die may include a first semiconductor substrate; and an edge conductive pad and a first conductive pad on a rear surface of the first semiconductor substrate. The edge conductive pad and a lateral surface of the second semiconductor die may overlap. The edge conductive pad may include the same material as the first conductive pad.

According to some embodiments of the present inventive concepts, a semiconductor package may include a buffer die; a plurality of memory dies sequentially stacked on the buffer die; a first underfill layer between the buffer die and a lowermost one of the plurality of memory dies; a plurality of second underfill layers, wherein a respective one of the plurality of second underfill layers is between adjacent ones of the plurality of memory dies; and a mold layer on a top surface of the buffer die, lateral surfaces of the plurality of memory dies, a lateral surface of the first underfill layer, and lateral surfaces of the plurality of second underfill layers. The buffer die may include a first semiconductor substrate; a first interlayer dielectric layer on a front surface of the first semiconductor substrate; a plurality of first wiring lines in the first interlayer dielectric layer; a first backside dielectric layer on a rear surface of the first semiconductor substrate; an edge conductive pad and a first conductive pad on the first backside dielectric layer; and a first through via that penetrates the first backside dielectric layer, the first semiconductor substrate, and a portion of the first interlayer dielectric layer to contact the first conductive pad. The first conductive pad and the plurality of memory dies may overlap. A portion of the edge conductive pad may be in contact with the mold layer. A top surface of the first conductive pad may be at a first height from the rear surface of the first semiconductor substrate. A top surface of the edge conductive pad may be at a second height from the rear surface of the first semiconductor substrate. The second height may be about 0.9 times to about 1.1 times the first height.

According to some embodiments of the present inventive concepts, a method of fabricating a semiconductor package may include manufacturing a wafer structure that has a plurality of device regions and a separation region between the plurality of device regions, wherein the wafer structure includes an edge conductive pad and a plurality of first conductive pads on the device regions; preparing a plurality of memory dies each including a plurality of first solder balls on a bottom surface thereof and a plurality of second conductive pads on a top surface thereof; bonding the plurality of first solder balls to the plurality of first conductive pads by bonding the plurality of memory dies on the plurality of device regions, wherein the plurality of memory dies are laminated with non-conductive film under the plurality of memory dies, wherein the non-conductive film is formed into a first underfill layer between the plurality of memory dies and the plurality of device regions, wherein a portion of the first underfill layer is formed into a fillet part that laterally protrudes from the plurality of memory dies and contacts the edge conductive pad; removing the fillet part; forming a mold layer on the wafer structure and the plurality of memory dies; and performing a singulation process on the wafer structure and the mold layer. The step of removing the fillet part may include irradiating a first laser to remove the fillet part and to leave a residual underfill pattern on the edge conductive pad; irradiating a second laser to remove the residual underfill pattern; and irradiating a third laser to clean a surface of the edge conductive pad.

### BRIEF DESCRIPTION OF DRAWINGS

FIG. 1 illustrates a plan view showing a semiconductor package according to some embodiments of the present inventive concepts.

FIG. 2 illustrates a cross-sectional view taken along line A-A′ of FIG. 1.

FIG. 3 illustrates an enlarged view showing section P1 of FIG. 2.

FIG. 4A illustrates a plan view showing a semiconductor package according to some embodiments of the present inventive concepts.

FIG. 4B illustrates an enlarged cross-sectional view taken along line B-B′ of FIG. 4A.

FIG. 5A illustrates a plan view showing a semiconductor package according to some embodiments of the present inventive concepts.

FIGS. 5B and 5C illustrate cross-sectional views taken along line B-B′ of FIG. 5A.

FIG. 6 illustrates a cross-sectional view taken along line A-A′ of FIG. 1.

FIG. 7 illustrates an enlarged view showing section P2 of FIG. 6.

FIG. 8A illustrates a cross-sectional view taken along line A-A′ of FIG. 1.

FIG. 8B illustrates an enlarged view showing section P1 of FIG. 8A.

FIGS. 9A to 9H illustrate cross-sectional views showing a method of fabricating a semiconductor package of FIG. 2.

FIGS. 10A to 10C illustrate enlarged view showing section P3 of FIG. 9E.

FIG. 11 illustrates a cross-sectional view showing a semiconductor package according to some embodiments of the present inventive concepts.

FIG. 12 illustrates a cross-sectional view showing a semiconductor package according to some embodiments of the present inventive concepts.

FIG. 13 illustrates a cross-sectional view showing a semiconductor package according to some embodiments of the present inventive concepts.

FIG. 14 illustrates a cross-sectional view showing a semiconductor package according to some embodiments of the present inventive concepts.

FIG. 15 illustrates a cross-sectional view showing a semiconductor package according to some embodiments of the present inventive concepts.

### DETAILED DESCRIPTION OF EXEMPLARY EMBODIMENTS

Some embodiments of the present inventive concepts will now be described in detail with reference to the accompanying drawings to aid in clearly explaining the present inventive concepts. In this description, such terms as “first” and “second” may be used to simply distinguish identical or similar components from each other, and the sequence of such terms may be changed in accordance with the order of mention. A semiconductor die may be called a semiconductor chip.

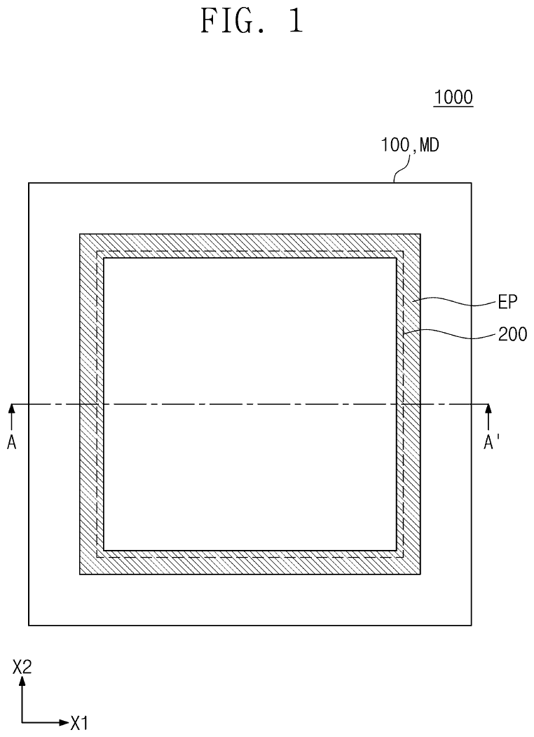

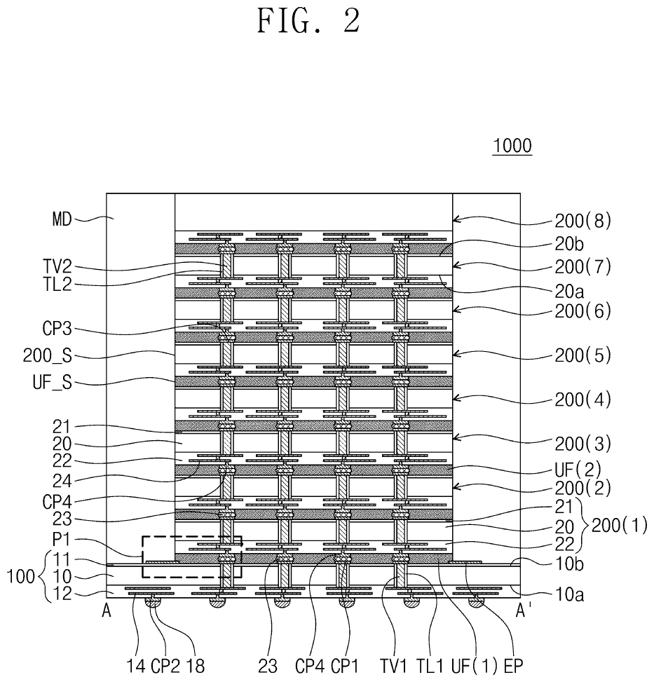

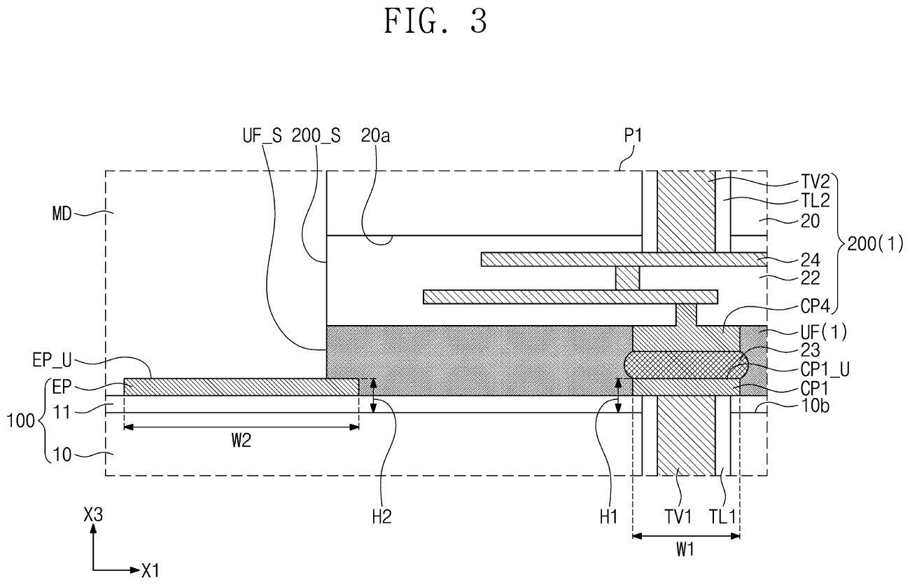

FIG. 1 illustrates a plan view showing a semiconductor package according to some embodiments of the present inventive concepts. FIG. 2 illustrates a cross-sectional view taken along line A-A′ of FIG. 1. FIG. 3 illustrates an enlarged view showing section P1 of FIG. 2.

Referring to FIGS. 1 to 3, a semiconductor package 1000 according to the present embodiment may include a first semiconductor die 100, second semiconductor dies 200, an underfill layer UF, and a mold layer MD. The second semiconductor dies 200 may be sequentially stacked on top of the first semiconductor die 100. The underfill layer UF may be interposed between the first and second semiconductor dies 100 and 200. The underfill layer UF may be called a non-conductive film. The mold layer MD may cover a top surface of the first semiconductor die 100, while covering lateral surfaces of the second semiconductor dies 200 and lateral surfaces of the underfill layers UF. The mold layer MD may include a dielectric resin, such as an epoxy molding compound (EMC). The mold layer MD may further include fillers, and the fillers may be dispersed in the dielectric resin.

The first semiconductor die 100 may be called a buffer die or a logic die. The second semiconductor die 200 may be called a memory die. The semiconductor package 1000 may be a high bandwidth memory (HBM) chip.

The first semiconductor die 100 may include a first semiconductor substrate 10. The first semiconductor substrate 10 may be a monocrystalline silicon substrate or a silicon-on-insulator (SOI) substrate. The first semiconductor substrate 10 may have a front surface 10a and a rear surface 10b that are opposite to each other. First transistors (not shown) may be disposed on the front surface 10a of the first semiconductor substrate 10. A first interlayer dielectric layer 12 may be disposed on the front surface 10a of the first semiconductor substrate 10. The first interlayer dielectric layer 12 may have a single-layered or multi-layered structure of at least one selected from silicon oxide, silicon nitride, silicon oxynitride, SiOCH, and SiCN. The first interlayer dielectric layer 12 may be provided therein with multi-layered first wiring lines 14. The first wiring lines 14 may include impurity-doped polysilicon or metal. The rear surface 10b of the first semiconductor substrate 10 may be covered with a first backside dielectric layer 11. The first backside dielectric layer 11 may be formed to have a single-layered or multi-layered structure of at least one selected from silicon oxide, silicon nitride, and SiCN.

First conductive pads CP1 and an edge conductive pad EP may be disposed on the first backside dielectric layer 11. The first conductive pads CP1 may be disposed adjacent to a center of the first semiconductor substrate 10. The first conductive pads CP1 may be utilized for transfer of electrical signals between the first semiconductor die 100 and the second semiconductor dies 200. Each of the first conductive pads CP1 may have a first width W1 in a first direction X1. Each of the first conductive pads CP1 may have a top surface CP1_U located at a first height H1 (in a third direction X3) from the rear surface 10b of the first semiconductor substrate 10.

As shown in FIG. 1, when viewed in plan, the edge conductive pad EP may have a tetragonal ring shape that surrounds the second semiconductor dies 200. The edge conductive pad EP may be formed of the same material as that of the first conductive pads CP1. The edge conductive pad EP and the first conductive pads CP1 may each have a single-layered or multi-layered structure of at least one selected from, for example, gold, copper, aluminum, nickel, titanium, and tantalum. The edge conductive pad EP may have a second width W2 in the first direction X1. The second width W2 may be greater than the first width W1. The edge conductive pad EP may have a top surface EP_U located at a second height H2 (in the third direction X3) from the rear surface 10b of the first semiconductor substrate 10. The second height H2 may be about 0.9 times to about 1.1 times the first height H1. The second height H2 may be substantially the same as the first height H1.

The edge conductive pad EP and the lateral surfaces 200_S of the second semiconductor dies 200 may overlap (i.e., a plane defined by each lateral surface 200_S of the second semiconductor dies 200 may intersect the edge conductive pad EP, as illustrated in FIG. 3). A portion of the edge conductive pad EP may be in contact with a first underfill layer UF(1) that is a lowermost one of the underfill layers UF, and another portion of the edge conductive pad EP may be in contact with the mold layer MD. In the present embodiment, the edge conductive pad EP may be applied with no electrical signal and electrically floated.

First through vias TV1 may penetrate the first backside dielectric layer 11, the first semiconductor substrate 10, and a portion of the first interlayer dielectric layer 12 to connect the first conductive pads CP to some of the first wiring lines 14. Each of the first through vias TV1 may include at least one metal selected from tungsten, copper, titanium, and tantalum. A first via dielectric layer TL1 may be interposed between the first through via TV1 and the first semiconductor substrate 10. The first via dielectric layer TL1 may be formed of, for example, silicon oxide. An air gap may be disposed in the first via dielectric layer TL1.

Second conductive pads CP2 may be disposed under the first interlayer dielectric layer 12. The second conductive pads CP2 may penetrate a portion of the first interlayer dielectric layer 12 to correspondingly come into contact with some of the first wiring lines 14. The second conductive pads CP2 may each have a single-layered or multi-layered structure of at least one metal selected from gold, copper, aluminum, nickel, titanium, and tantalum. The second conductive pads CP2 may be provided thereunder with first solder balls 18 bonded thereto. The first solder balls 18 may be formed of, for example, SnAg.

FIG. 2 depicts that eight second semiconductor dies 200 are provided and sequentially stacked on top of each other. The present inventive concepts are not limited thereto, and the number of the second semiconductor dies 200 may be less or greater than eight. For example, the number of the second semiconductor dies 200 may be four or twelve. The second semiconductor dies 200 may be of the same memory die, for example, DRAM chip.

Each of the second semiconductor dies 200 may include a second semiconductor substrate 20. The second semiconductor substrate 20 may be a monocrystalline silicon substrate or a silicon-on-insulator (SOI) substrate. The second semiconductor substrate 20 may have a front surface 20a and a rear surface 20b that are opposite to each other. Second transistors (not shown) may be disposed on the front surface 20a of the second semiconductor substrate 20. A second interlayer dielectric layer 22 may be disposed on the front surface 20a of the second semiconductor substrate 20. The second interlayer dielectric layer 22 may have a single-layered or multi-layered structure of at least one selected from silicon oxide, silicon nitride, silicon oxynitride, SiOCH, and SiCN. The second interlayer dielectric layer 22 may be provided therein with multi-layered second wiring lines 24. The second wiring lines 24 may include impurity-doped polysilicon or metal.

Fourth conductive pads CP4 may be disposed under the second interlayer dielectric layer 22. The fourth conductive pads CP4 may penetrate a portion of the second interlayer dielectric layer 22 to correspondingly come into contact with some of the second wiring lines 24. The fourth conductive pads CP4 may have a single-layered or multi-layered structure of at least one metal selected from gold, copper, aluminum, nickel, titanium, and tantalum. The fourth conductive pads CP4 may be provided thereunder with second solder balls 23 bonded thereto. The second solder balls 23 may be formed of, for example, SnAg.

The second solder balls 23 may lie between and connect to each other the first conductive pad CP1 and the fourth conductive pad CP4 that are adjacent to each other, and may also lie between and connect to each other the third conductive pad CP3 and the fourth conductive pad CP4 that are adjacent to each other.

In each of the second semiconductor dies 200(1) to 200(7) except for an uppermost second semiconductor die 200(8), the rear surface 20b of the second semiconductor substrate 20 may be covered with a second backside dielectric layer 21. The second backside dielectric layer 21 may be formed to have a single-layered or multi-layered structure of at least one selected from silicon oxide, silicon nitride, and SiCN. Third conductive pads CP3 may be disposed on the second backside dielectric layer 21. Each of the third conductive pads CP3 may have a single-layered or multi-layered structure of at least one metal selected from, for example, gold, copper, aluminum, nickel, titanium, and tantalum. Second through vias TV2 may penetrate the second backside dielectric layer 21, the second semiconductor substrate 20, and a portion of the second interlayer dielectric layer 22 to connect the third conductive pads CP3 to some of the second wiring lines 24. Each of the second through vias TV2 may include at least one metal selected from tungsten, copper, titanium, and tantalum. A second via dielectric layer TL2 may be interposed between the second through via TV2 and the second semiconductor substrate 20. The second via dielectric layer TL2 may be formed of, for example, silicon oxide. An air gap may be disposed in the second via dielectric layer TL2.

The uppermost second semiconductor die 200(8) may include none of the second backside dielectric layer 21, the third conductive pads CP3, the second through vias TV2, and the second via dielectric layer TL2. The second semiconductor substrate 20 of the uppermost second semiconductor die 200(8) may have a thickness greater than those of the second semiconductor substrates 20 of the second semiconductor dies 200(1) to 200(7) that underlie the uppermost second semiconductor die 200(8). The rear surface 20b of the second semiconductor substrate 20 included in the uppermost second semiconductor die 200(8) may be coplanar with a top surface of the mold layer MD.

The underfill layer UF may be formed of a non-conductive film (NCF). The underfill layer UF may be called a non-conductive film. The underfill layer UF may include a thermosetting resin or a photo-curable resin. The underfill layer UF may further include organic fillers or inorganic fillers. The organic fillers may include, for example, a polymer material. The inorganic fillers may include, for example, silicon oxide (SiO2).

The underfill layers UF may include a first underfill layer UF(1) interposed between a lowermost second semiconductor die 200(1) and the first semiconductor die 100, and may also include second underfill layers UF(2) interposed between the second semiconductor dies 200. The underfill layers UF may have their lateral surfaces UF_S aligned with lateral surfaces 200_S of the second semiconductor dies 200 (i.e., the lateral surfaces UF_S of the underfill layers UF and the lateral surfaces 200_S of the second semiconductor dies 200 may be co-planar). The lateral surfaces UF_S of the underfill layers UF may overlap the edge conductive pad EP (i.e., a plane defined by the lateral surfaces UF_S of the underfill layers UF may intersect the edge conductive pad EP, as illustrated in FIG. 2). The underfill layers UF may not laterally protrude from the second semiconductor dies 200.

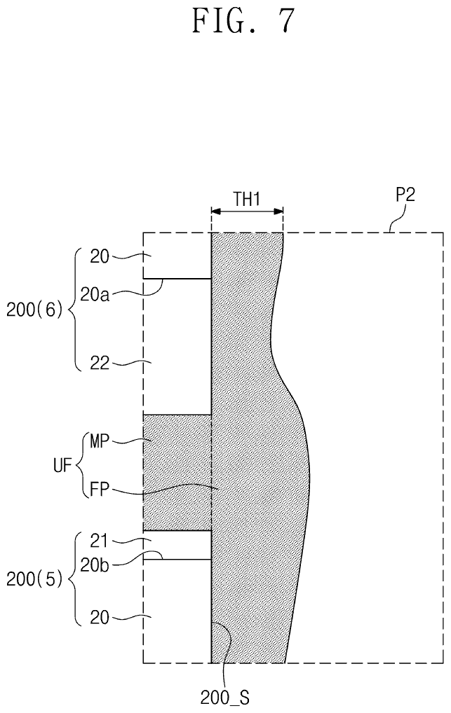

The semiconductor package 1000 according to the present inventive concepts may have the structure discussed above, and thus it may be possible to prevent or minimize warpage phenomenon and delamination between the mold layer MD and the semiconductor dies 100 and 200. It may also be possible to present or minimize non-wet failure of the second solder balls 23. Accordingly, the semiconductor package 1000 may improve in reliability. In a method of fabricating the semiconductor package 1000 according to the present inventive concepts, a laser may be used to effectively remove fillet parts FP (FIG. 7) of the underfill layers UF, and the edge conductive pad EP may prevent the first semiconductor die 100 from damage caused by the laser. As the edge conductive pad EP and the first conductive pads CP1 are simultaneously formed of the same material, a separate process for forming the edge conductive pad EP may not be needed to simplify the process.

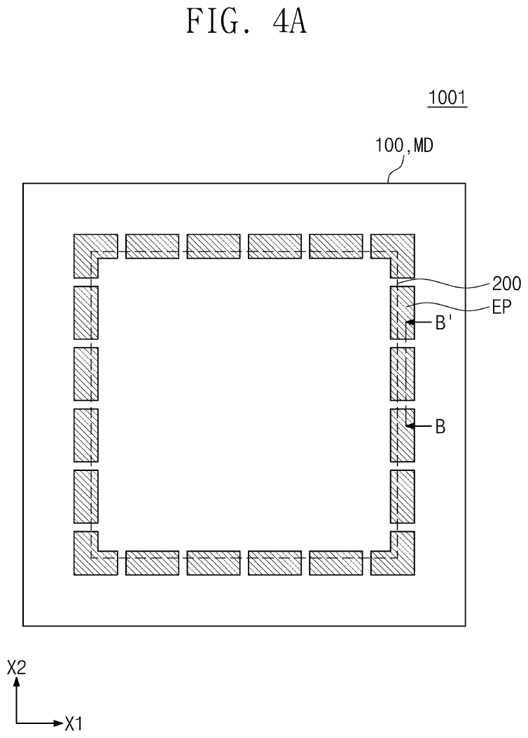

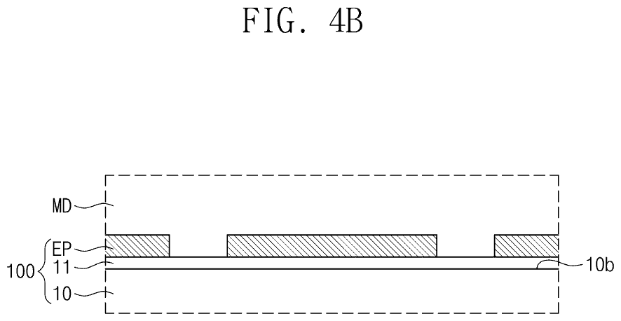

FIG. 4A illustrates a plan view showing a semiconductor package according to some embodiments of the present inventive concepts. FIG. 4B illustrates an enlarged cross-sectional view taken along line B-B′ of FIG. 4A.

Referring to FIGS. 4A and 4B, in a semiconductor package 1001 according to the present embodiment, the edge conductive pad EP may be provided in plural, and the plurality of edge conductive pads EP may be spaced apart from each other along the first and second directions X1 and X2. When viewed in plan, each of the edge conductive pads EP may have a bar shape or an L shape. Between the edge conductive pads EP, the mold layer MD may be in contact with a top surface of the first backside dielectric layer 11. Other configurations may be identical or similar to those discussed above.

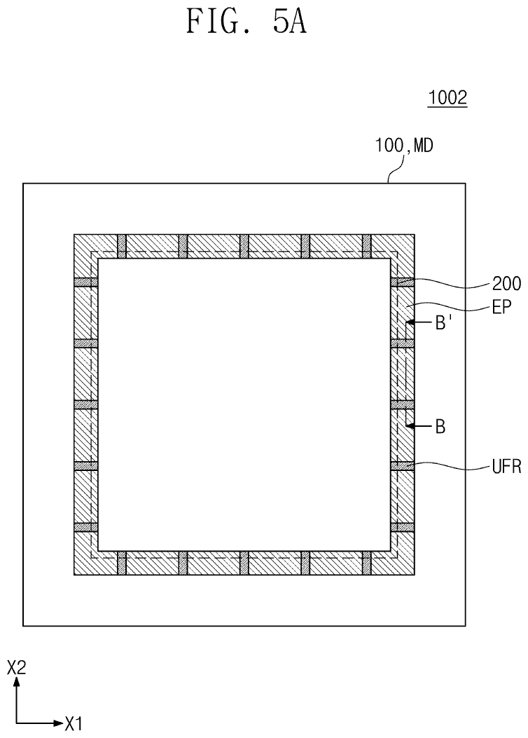

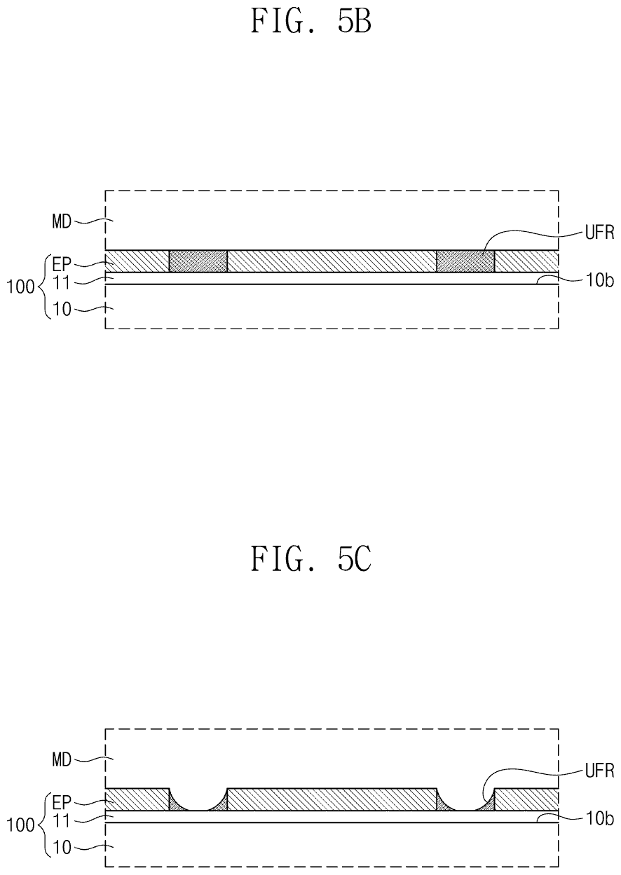

FIG. 5A illustrates a plan view showing a semiconductor package according to some embodiments of the present inventive concepts. FIGS. 5B and 5C illustrate cross-sectional views taken along line B-B′ of FIG. 5A.

Referring to FIGS. 5A to 5C, in a semiconductor package 1002 according to the present embodiment, the edge conductive pad EP may be provided in plural, and the plurality of edge conductive pads EP may be spaced apart from each other along the first and second directions X1 and X2. When viewed in plan, each of the edge conductive pads EP may have a bar shape or an L shape. A residual underfill pattern UFR may be disposed between the edge conductive pads EP. The residual underfill pattern UFR may be formed of the same material as that of the underfill layers UF. As shown in FIG. 5B, the residual underfill pattern UFR may fill a space between the edge conductive pads EP. Alternatively, as shown in FIG. 5C, the residual underfill pattern UFR may cover lateral surfaces of the edge conductive pads EP and partially expose a top surface of the first backside dielectric layer 11. Other configurations may be identical or similar to those discussed above.

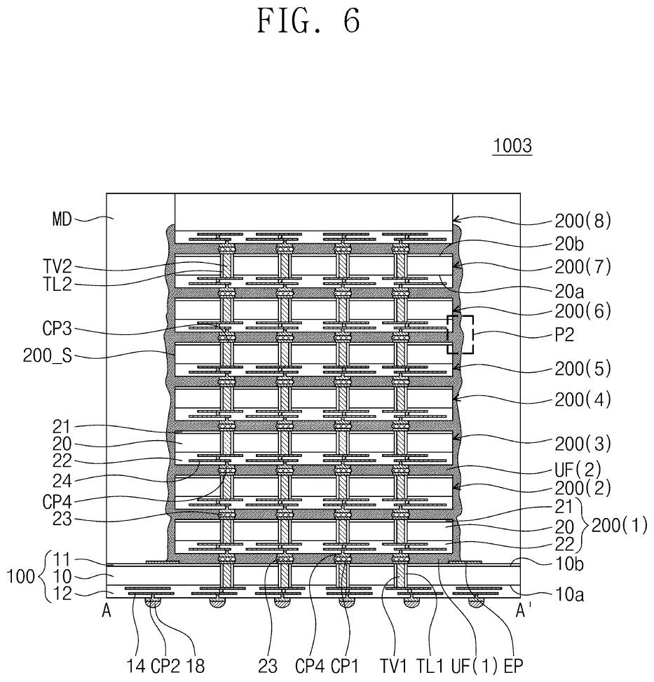

FIG. 6 illustrates a cross-sectional view taken along line A-A′ of FIG. 1. FIG. 7 illustrates an enlarged view showing section P2 of FIG. 6.

Referring to FIGS. 6 and 7, in a semiconductor package 1003 according to the present embodiment, the underfill layers UF may extend to cover the lateral surfaces 200_S of the second semiconductor dies 200. The underfill layers UF may meet and come into contact with each other on the lateral surfaces 200_S of the second semiconductor dies 200, appearing as a single unitary piece. The underfill layer UF may include a main part MP that intervenes between the first and second semiconductor dies 100 and 200 and a fillet part FP that laterally protrudes from the lateral surfaces 200_S of the second semiconductor dies 200. The main part MP and the fillet part FP may be formed of the same material, and an invisible interface may be present between the main part MP and the fillet part FP. The fillet FP may have a thickness TH1 that is changed depending on position and has an uneven lateral surface. The thickness TH1 of the fillet part FP may range from about 0 μm to about 50 μm. As the thickness TH1 of the fillet part FP is equal to or less than about 50 μm, it may be possible to prevent or minimize delamination between the mold layer MD and the first semiconductor die 100. Other configurations may be identical or similar to those discussed above.

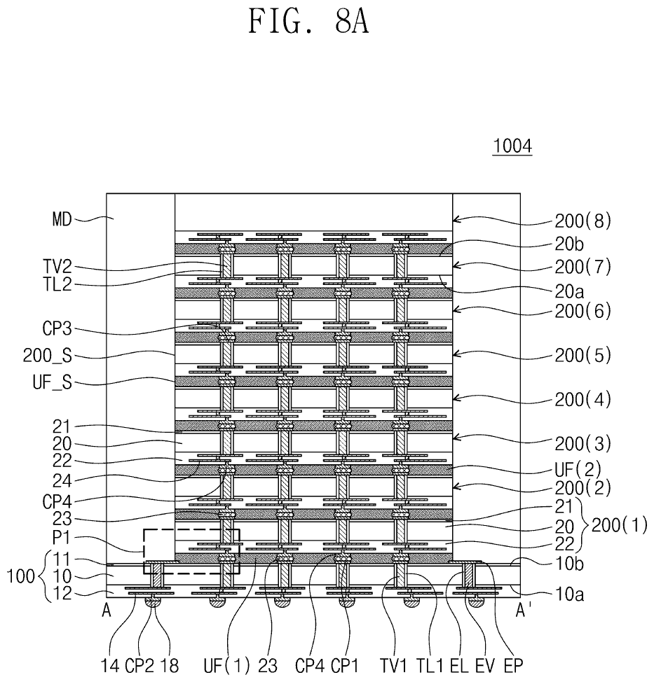

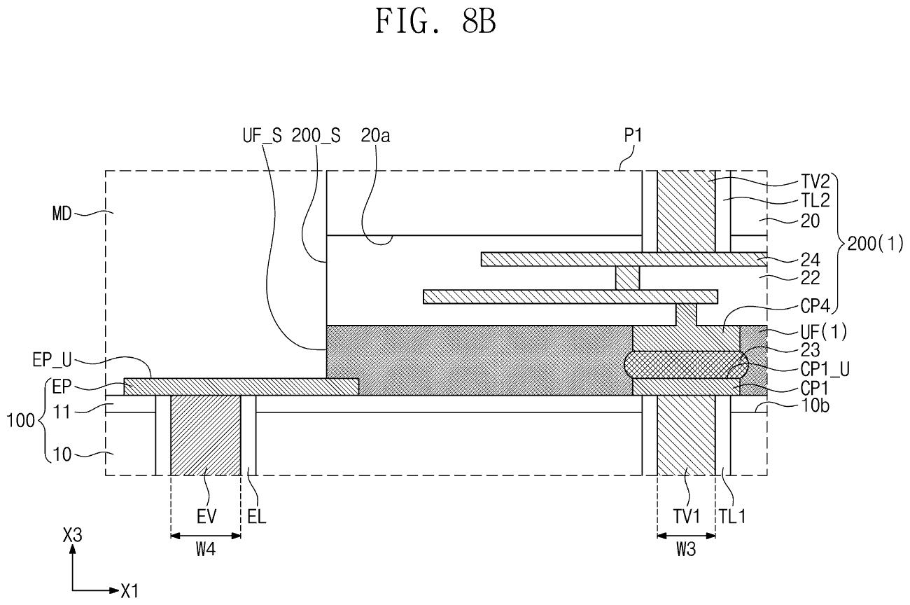

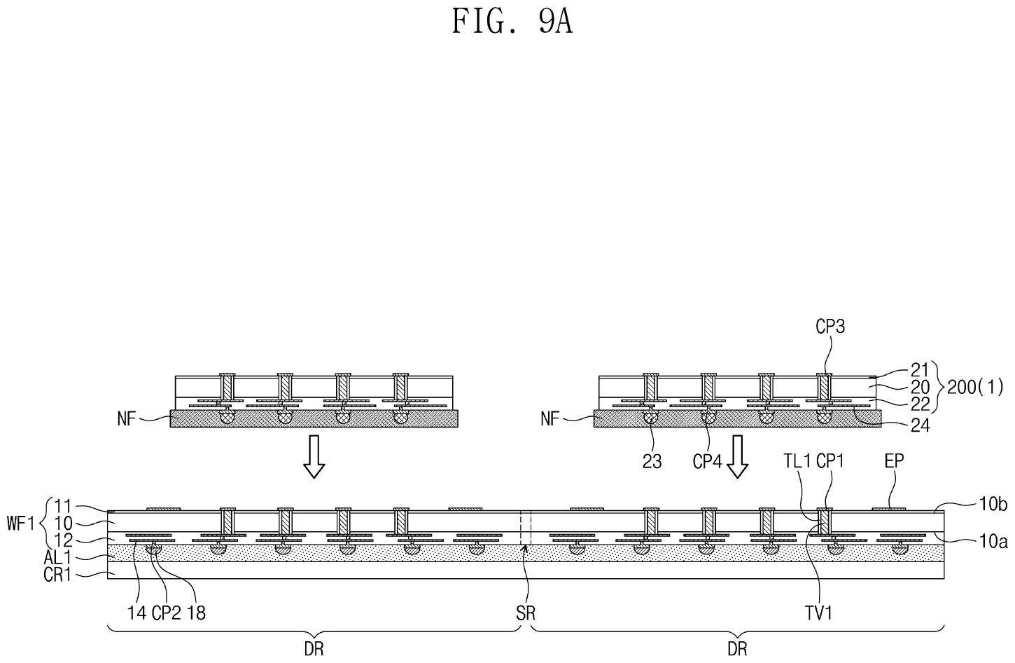

FIG. 8A illustrates a cross-sectional view taken along line A-A′ of FIG. 1. FIG. 8B illustrates an enlarged view showing section P1 of FIG. 8A.

Referring to FIGS. 8A and 8B, a semiconductor package 1004 according to the present embodiment may further include an edge through via EV connected to the edge conductive pad EP. The edge through via EV may penetrate the first backside dielectric layer 11, the first semiconductor substrate 10, and a portion of the first interlayer dielectric layer 12 to come into contact with the edge conductive pad EP. An edge through via dielectric layer EL may be interposed between the edge through via EV and the first semiconductor substrate 10. The edge through via EV may be present to effectively discharge heat generated from the first semiconductor die 100. The edge through via EV may be called a thermal via. The edge through via EV may include the same material as that of the first through via TV1. Alternatively, the edge through via EV may include a material whose thermal conductivity is greater than that of a material included in the first through via TV1. The first through via TV1 may have a third width W3. The edge through via EV may have a fourth width W4. The fourth width W4 may be equal to or greater than the third width W3. Under these conditions, the edge through via EV may effectively discharge heat. The edge through via EV may be applied with no electrical signal and electrically floated. Other configurations may be identical or similar to those discussed above.

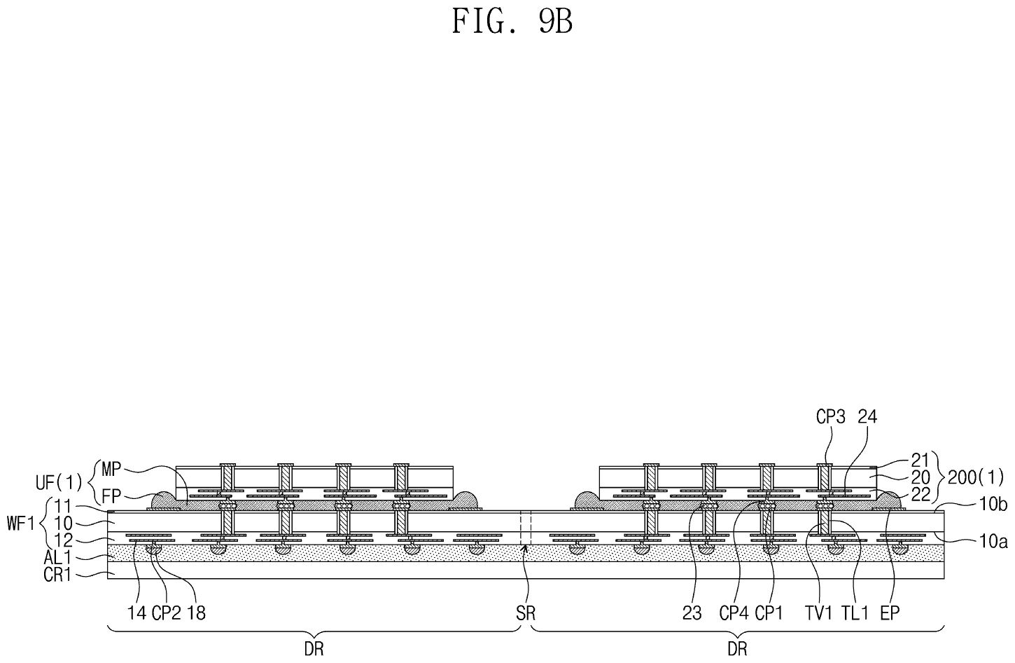

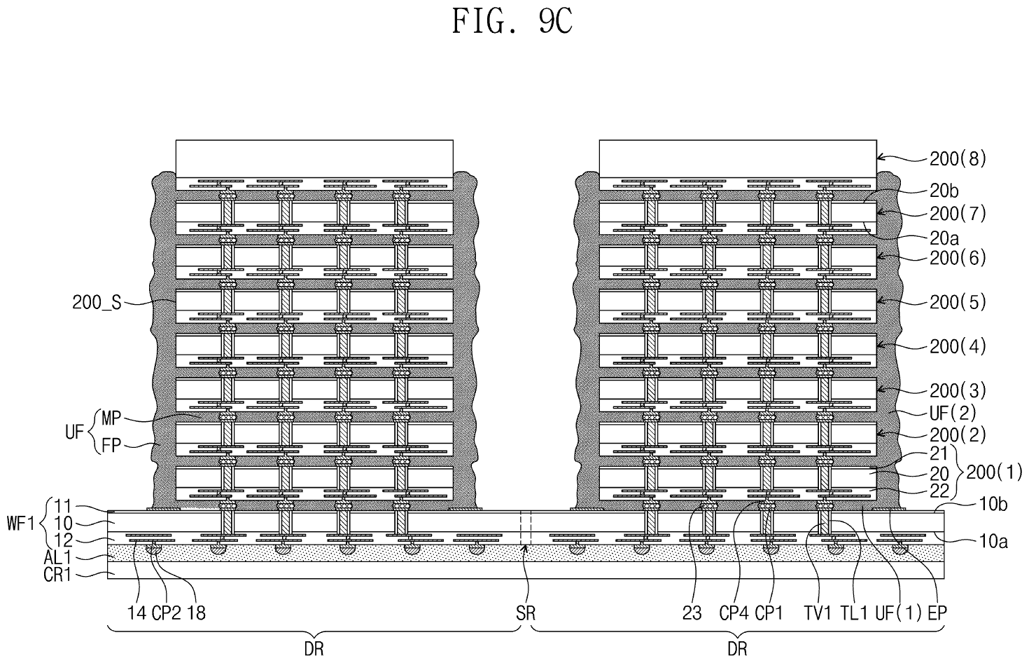

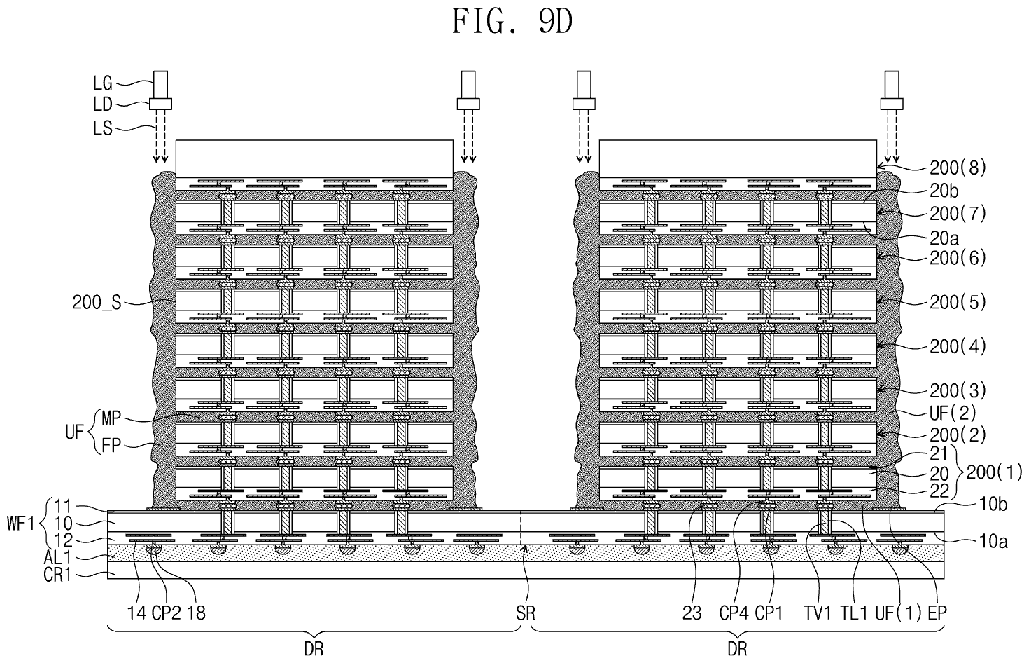

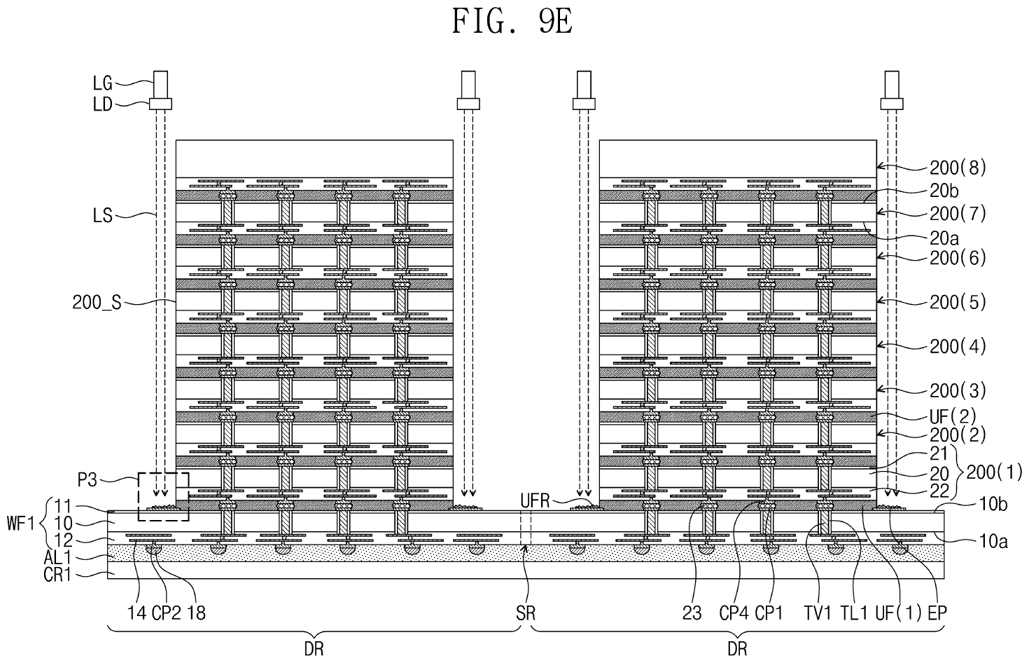

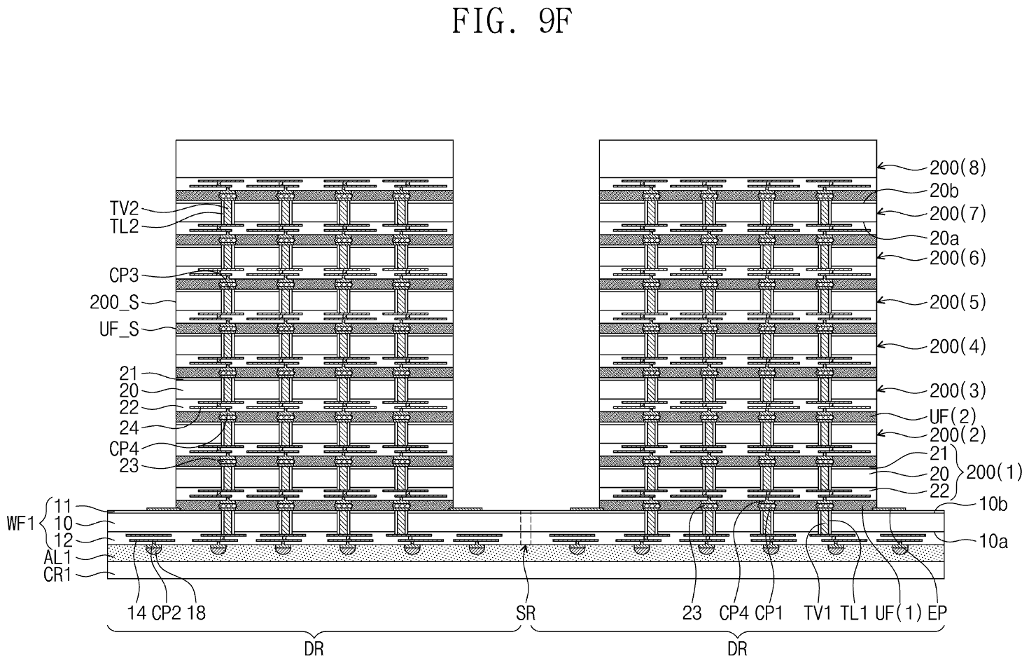

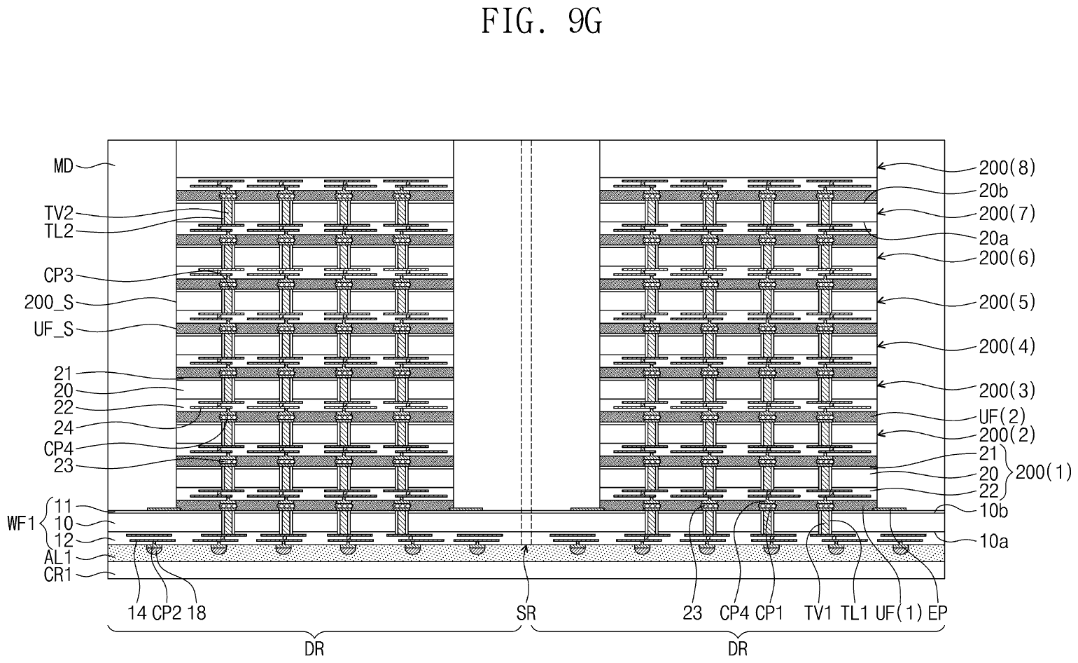

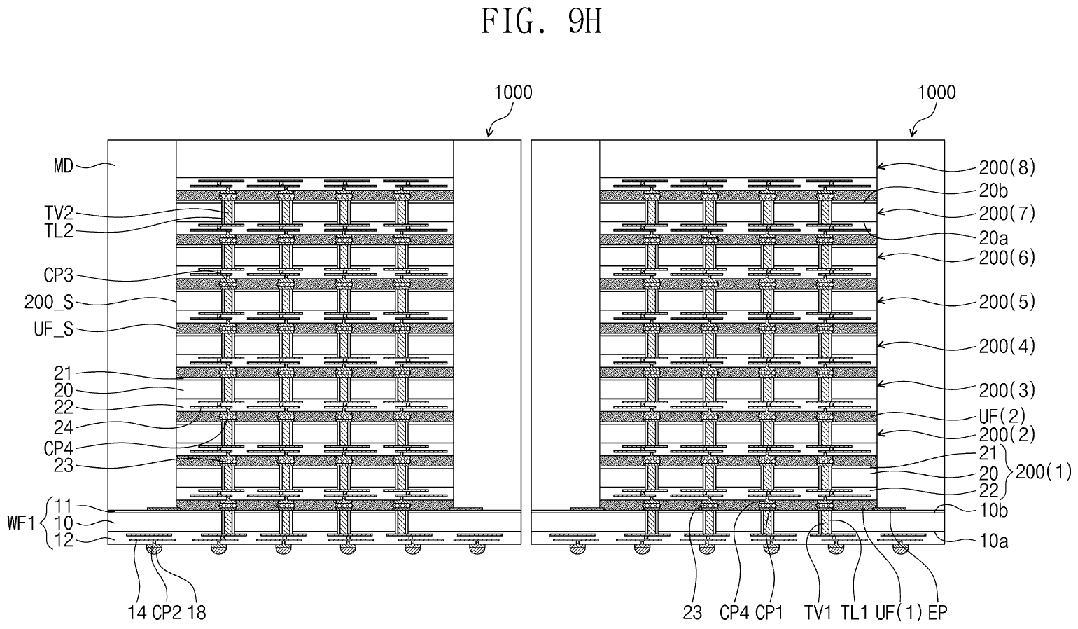

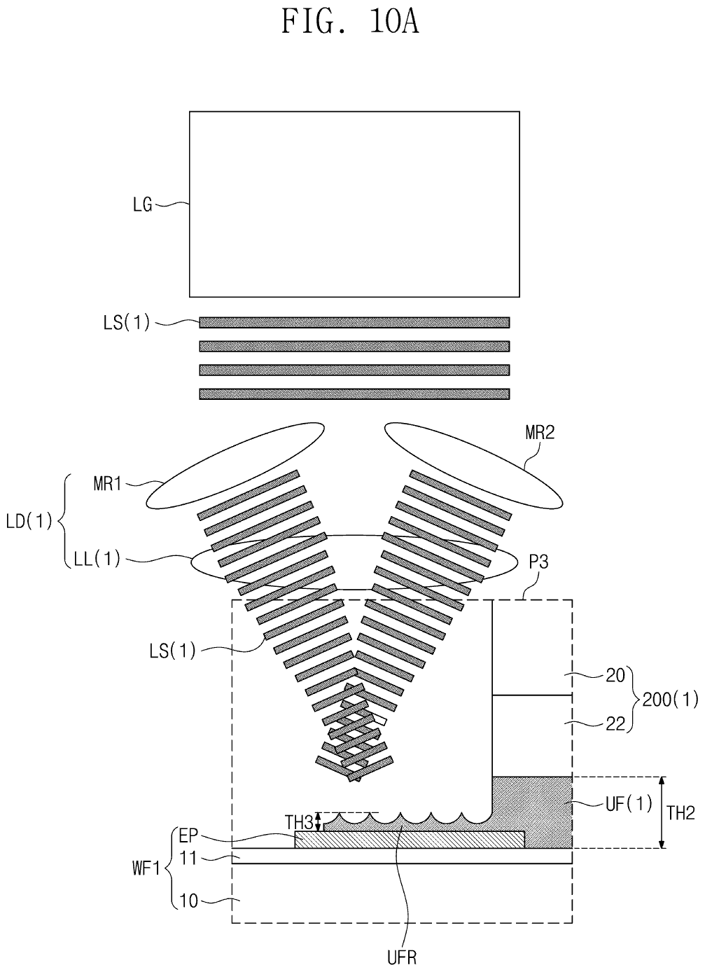

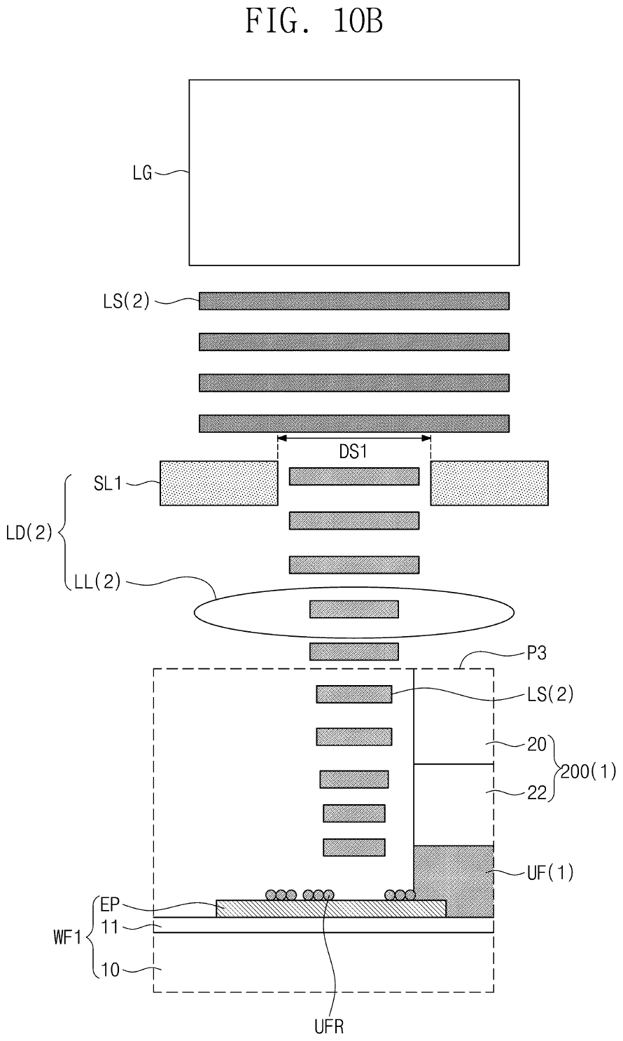

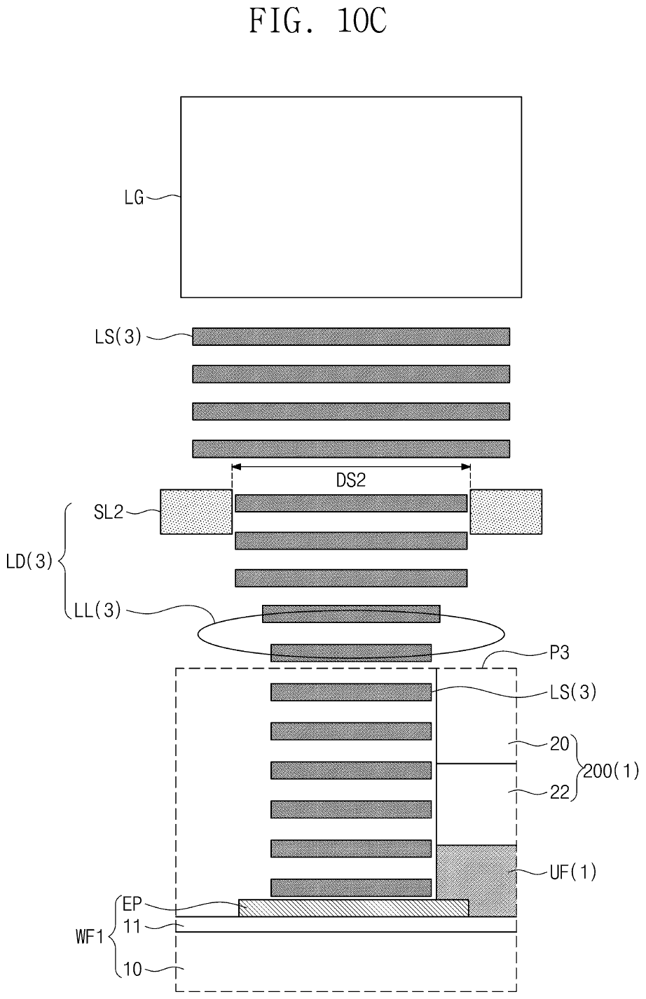

FIGS. 9A to 9H illustrate cross-sectional views showing a method of fabricating a semiconductor package of FIG. 2. FIGS. 10A to 10C illustrate enlarged view showing section P3 of FIG. 9E.

Referring to FIG. 9A, a first wafer structure WF1 may be prepared. The first wafer structure WF1 may have device regions DR and a separation region SR between the device regions DR. On each device region DR, the first wafer structure WF1 may have a structure the same as that of the first semiconductor die 100 discussed with reference to FIG. 2. The first wafer structure WF1 may include a first through via TV1 and a first via dielectric layer TL1 formed therein. A first interlayer dielectric layer 12, first wiring lines 14, second conductive pads CP2, and first solder balls 18 may be formed on a front surface 10a of the first wafer structure WF1. The first wafer structure WF1 may be bonded through an adhesion layer AL1 to a carrier substrate CR1. A rear surface 10b of the first wafer structure WF1 may be ground to expose the first through via TV1 and the first via dielectric layer TL1 and to form a first backside dielectric layer 11. A conductive layer may be stacked on top of and patterned on the first backside dielectric layer 11 to form first conductive pads CP1 and edge conductive pads EP.

Referring still to FIG. 9A, second semiconductor dies 200 may be prepared. The second semiconductor dies 200 may have the same structure as that of the lowermost second semiconductor dies 200(1). Second solder balls 23 may be bonded to bottom surfaces of the second semiconductor dies 200. The device regions DR may be provided thereon with the lowermost second semiconductor dies 200(1) which are laminated with non-conductive films NF on bottom surfaces thereof.

Referring to FIG. 9B, a thermocompression process may be performed to allow the second solder balls 23 to penetrate the non-conductive films NF, and thus the second solder balls 23 may be correspondingly in contact with and bonded to the first conductive pads CP1. In the thermocompression process, the non-conductive films NF may be melted to form first underfill layers UF(1) that fill spaces between the first wafer structure WF1 and the lowermost second semiconductor dies 200(1). The first underfill layers UF(1) may each include a main part MP that intervenes between the first wafer structure WF1 and the lowermost second semiconductor die 200(1) and a fillet part FP that laterally protrudes from the lowermost second semiconductor die 200(1). The fillet part FP may be formed to cover a portion of the edge conductive pad EP and to have a rounded lateral surface.

During the thermocompression process, the non-conductive films NF may suppress/prevent/minimize warpage of the second semiconductor dies 200. Thus, the second semiconductor dies 200 may be flat mounted.

Referring to FIG. 9C, identical or similar to that discussed with reference to FIGS. 9A and 9B, the lowermost second semiconductor dies 200(1) may be provided thereon with next lowermost second semiconductor dies 200(2) which are laminated with non-conductive films NF thereunder, and a thermocompression process may be performed to bond the next lowermost second semiconductor dies 200(2) onto the lowermost second semiconductor dies 200(1). The process above may be repeatedly performed up to bonding of uppermost second semiconductor dies 200(8). The fillet parts FP of the underfill layers UF may meet each other to cover lateral surfaces 200_S of the second semiconductor dies 200.

Referring to FIGS. 9D to 9F and 10A to 10C, a laser LS may be irradiated to the fillet parts FP of the underfill layers UF to remove at least portions of the fillet parts FP of the underfill layers UF. For example, a trimming process may be performed on the fillet parts FP of the underfill layers UF. Thus, the lateral surfaces 200_S of the second semiconductor dies 200 may be exposed as shown in FIG. 2 or the fillet parts FP of the underfill layers UF may partially remain to cover the lateral surfaces 200_S of the second semiconductor dies 200 as shown in FIG. 6. The laser LS may be generated from a laser generator LG and may pass through an optic section LD, thereby traveling to the fillet parts FP of the underfill layers UF. The fillet parts FP of the underfill layers UF may be removed by three steps.

For example, referring to FIGS. 9D, 9E, and 10A, as a first steps, a first laser LS(1) may be irradiated to remove most of the fillet parts FP and to leave a residual underfill pattern UFR on the edge conductive pad EP. The first laser LS(1) may be generated from the laser generator LG. The first laser LS(1) may pass through a first optical section LD(1). In the first step, the first optical section LD(1) may include a first mirror (or an X mirror) MR1, a second mirror (or a Y mirror) MR2, and a first lens LL(1). The first lens LL(1) may be an F-theta lens. The first laser LS(1) may be reflected from the first mirror MR1 and the second mirror MR2 to pass through the first lens LL(1), thereby being irradiated to the fillet parts FP of the underfill layers UF. The first laser LS(1) may have a first peak power. The first peak power may be an extreme high-peak power. The first laser LS(1) may have a pulse width of, for example, about 100 femtoseconds to about 500 femtoseconds. The first laser LS(1) may have a wavelength of about 510 nm to about 520 nm. The first laser LS(1) may enable cold ablation to remove most of the fillet parts FP of the underfill layers UF and to leave a residual underfill pattern UFR, without damage to a surface of the edge conductive pad EP or a surface of the first wafer structure WF1. A third thickness TH3 of the residual underfill pattern UFR may be about 0.01 times to about 0.1 times a second thickness TH2 of the first underfill layer UF(1). The residual underfill pattern UFR may protect the surface of the edge conductive pad EP.

Referring to FIG. 10B, as a second step, a second laser LS(2) may be irradiated to remove the residual underfill pattern UFR. The second laser LS(2) may be generated from the laser generator LG. The second laser LS(2) may pass through a second optical section LD(2). In the second step, the second optical section LD(2) may include a first slit SL1 and a second lens LL(2). The first slit SL1 may provide an interstice of a first interval DS1. The second laser LS(2) may pass through the interstice of the first slit SL(1) and the second lens LL(2) to travel to the residual underfill pattern UFR. The second laser LS(2) may have a second peak power. The second peak power may be less than the first peak power. An energy of the second laser LS(2) may be less than that of the first laser LS(1). The second laser LS(2) may have a pulse width greater than that of the first laser LS(1). The second laser LS(2) may have a pulse width of, for example, about 1 nanosecond to about 20 nanoseconds. A wavelength of the second laser LS(2) may be greater than that of the first laser LS(1). For example, the wavelength of the second laser LS(2) may range from about 521 nm to about 540 nm. The second laser LS(2) may induce a shock wave. The second laser LS(2) may apply heat to the residual underfill pattern UFR. Thus, there may be a reduction in adhesion between the residual underfill pattern UFR and the edge conductive pad EP, and the residual underfill pattern UFR may be melted, evaporated, and removed. Accordingly, the surface of the edge conductive pad EP may be exposed.

Referring to FIGS. 9F and 10C, as a third step, a third laser LS(3) may be irradiated to clean the surface of the edge conductive pad EP. The third laser LS(3) may be generated from the laser generator LG. The third laser LS(3) may pass through a third optical section LD(3). In the third step, the third optical section LD(3) may include a second slit SL2 and a third lens LL(3). The second slit SL2 may provide an interstice of a second interval DS2. The second interval DS2 may be greater than the first interval DS1 of FIG. 10B. The third laser LS(3) may pass through the interstice of the second slit SL(2) and the third lens LL(2) to travel to the surface of the edge conductive pad EP. The third laser LS(3) may have a third peak power. The third peak power may be less than the first peak power. An energy of the third laser LS(3) may be less than that of the second laser LS(2). The third laser LS(3) may have a pulse width greater than that of the first laser LS(1). The pulse width of the third laser LS(3) may range from about 1 nanosecond to about 20 nanoseconds. A wavelength of the third laser LS(3) may be greater than that of the first laser LS(1). For example, the wavelength of the third laser LS(3) may range from about 521 nm to about 540 nm. The third laser LS(3) may clean the surface of the edge conductive pad EP without damage to the surface of the edge conductive pad EP.

Subsequently, referring to FIG. 9G, a mold layer MD may be formed to cover the first wafer structure WF1 and the second semiconductor dies 200. The mold layer MD may undergo a grinding process to remove a portion of the mold layer MD and to top surfaces of the uppermost second semiconductor dies 200(8).

Referring to FIG. 9H, the adhesive layer AL1 and the carrier substrate CR1 may be removed under the first wafer structure WF1. A singulation process may be performed to cut the separation region SR. A semiconductor package 1000 may thus be fabricated as shown in FIG. 2.

In a method of fabricating a semiconductor package according to the present inventive concepts, a laser may be used to remove the fillet parts FP of the underfill layers UF, and in this case, the first wafer structure WF1 may be prevented from damage. The edge conductive pad EP may serve to block a laser beam and to protect the first wafer structure WF1. As a result, process failure may be reduced to increase a yield.

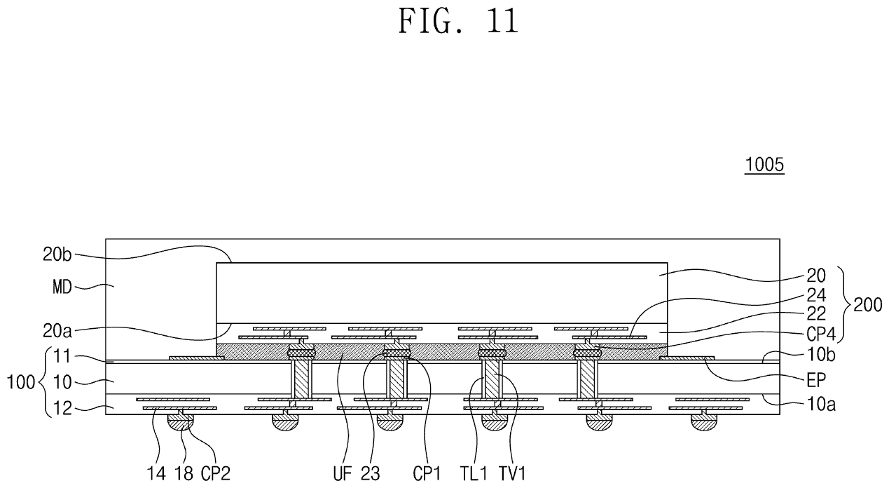

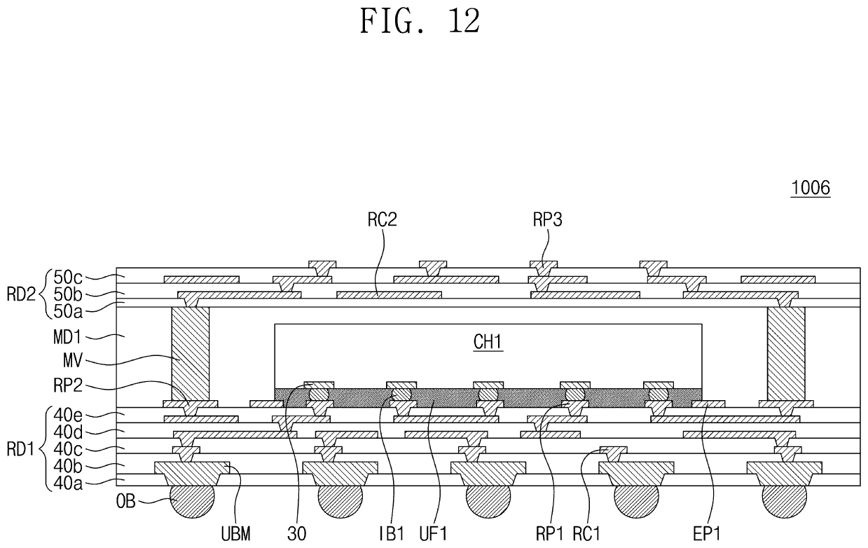

FIG. 11 illustrates a cross-sectional view showing a semiconductor package according to some embodiments of the present inventive concepts.

Referring to FIG. 11, a semiconductor package 1005 according to the present embodiment may include a first semiconductor die 100, a second semiconductor die 200, an underfill layer UF, and a mold layer MD. The first semiconductor die 100 may have a structure the same as that of the first semiconductor die 100 shown in FIG. 2. The second semiconductor die 200 may be the same as the uppermost second semiconductor die 200(8) of FIG. 2. The mold layer MD may cover a top surface of the second semiconductor die 200. Other configurations may be identical or similar to those discussed above.

FIG. 12 illustrates a cross-sectional view showing a semiconductor package according to some embodiments of the present inventive concepts.

Referring to FIG. 12, a semiconductor package 1006 according to the present embodiment may include a first substrate RD1, a first semiconductor device CH1, a first mold layer MD1, a second substrate RD2, a first underfill layer UF1, and mold vias MV. Each of the first substrate RD1 and the second substrate RD2 may be a redistribution substrate or a double-sided or multi-layered printed circuit board. The first substrate RD1 may be called a first redistribution substrate, and the second substrate RD2 may be called a second redistribution substrate. The first substrate RD1 may include first dielectric layers 40a to 40e, under bumps UBM, first substrate inner patterns RC1, first and second conductive pads RP1 and RP2, and a first edge conductive pad EP1. The first dielectric layers 40a to 40e may each be, for example, a photo-imageable dielectric (PID).

The under bumps UBM, the first substrate inner patterns RC1, the first and second conductive pads RP1 and RP2, and the first edge conductive pad EP1 may each be formed of a conductive material. The under bumps UBM, the first substrate inner patterns RC1, the first and second conductive pads RP1 and RP2, and the first edge conductive pad eP1 may each include at least one metal selected from titanium, titanium nitride, tantalum, tantalum nitride, copper, aluminum, nickel, and gold. The first and second conductive pads RP1 and RP2 and the first edge conductive pad EP1 may be formed of the same material, and may have their top surfaces located at the same height (i.e., the top surfaces of the first and second conductive pads RP1 and RP2 and the first edge conductive pad EP1 may be co-planar).

The under bumps UBM may penetrate a lowermost one 40a of the first dielectric layers 40a to 40e. The under bumps UBM may be provided thereon with external connection terminals OB bonded thereto. The external connection terminals OB may be at least one selected from, for example, solder balls, conductive bumps, and conductive pillars. The external connection terminals OB may include at least one selected from, for example, tin, nickel, silver, copper, gold, and aluminum.

The first substrate inner patterns RC1 may be interposed between the first dielectric layers 40a to 40e, and may penetrate some of the first dielectric layers 40a to 40e. The first and second conductive pads RP1 and RP2 may be positioned on and penetrate an uppermost one 40e of the first dielectric layers 40a to 40e.

The second substrate RD2 may include second dielectric layers 50a to 50c, second substrate inner patterns RC2, and third conductive pads RP3. The second dielectric layers 50a to 50c may each be, for example, a photo-imageable dielectric (PID). The second substrate inner patterns RC2 and the third conductive pads RP3 may each be formed of a conductive material. The second substrate inner patterns RC2 and the third conductive pads RP3 may each include at least one selected from titanium, titanium nitride, tantalum, tantalum nitride, copper, aluminum, nickel, and gold.

The first substrate inner patterns RC1 and the second substrate inner patterns RC2 may each include a diffusion barrier layer and a wiring line part. The diffusion barrier layer may cover a bottom surface of the wiring line part. The diffusion barrier layer may include at least one selected from titanium, titanium nitride, tantalum, and tantalum nitride. The wiring line part may include metal, such as copper, aluminum, nickel, and gold. The first substrate inner patterns RC1 and the second substrate inner patterns RC2 may each include a via part that penetrates one of the first dielectric layers 40a to 40e and the second dielectric layers 50a to 50c, and may also include a line part and a pad part on the via part. The via part may have a width that decreases in a downward direction.

The first semiconductor device CH1 may be called a semiconductor chip or a semiconductor die. The first semiconductor device CH1 may be one selected from a microelectromechanical system (MEMS) device chip, an application specific integrated circuit (ASIC) chip, and a memory device chip such as Flash memory, DRAM, SRAM, EEPROM, PRAM, MRAM, ReRAM, high bandwidth memory (HBM), and hybrid memory cubic (HMC). The first semiconductor device CH1 may be provided with chip conductive pads 30 on a lower end thereof.

First inner connection members IB1 may be interposed between and connect the chip conductive pads 30 and the first conductive pads RP1. The first inner connection members IB1 may be, for example, at least one selected from solder balls, conductive bumps, and conductive pillars. The first inner connection members IB1 may include, for example, at least one selected from tin, nickel, silver, copper, gold, and aluminum.

The first underfill layer UF1 may be interposed between the first semiconductor device CH1 and the first substrate RD1. A portion of the first edge conductive pad EP1 may be in contact with the first underfill layer UF1, and another portion of the first edge conductive pad EP1 may be in contact with the first mold layer MD1. A lateral surface of the first semiconductor device CH1 and a lateral surface of the first underfill layer UF1 may be aligned with each other (i.e., the lateral surface of the first semiconductor device CH1 and the lateral surface of the first underfill layer UF1 may be co-planar) and may overlap the first edge conductive pad EP1, as illustrated in FIG. 12 (i.e., a plane defined by the lateral surface of the first semiconductor device CH1 and a plane defined by the lateral surface of the first underfill layer UF1 may intersect or overlap with a surface of the first edge conductive pad EP1).

Each of the mold vias MV may penetrate the first mold layer MD1. The mold vias MV may electrically connect the first substrate RD1 to the second substrate RD2. Each of the mold vias MV may be formed of copper. The mold vias MV may be in contact with the second conductive pads RP2.

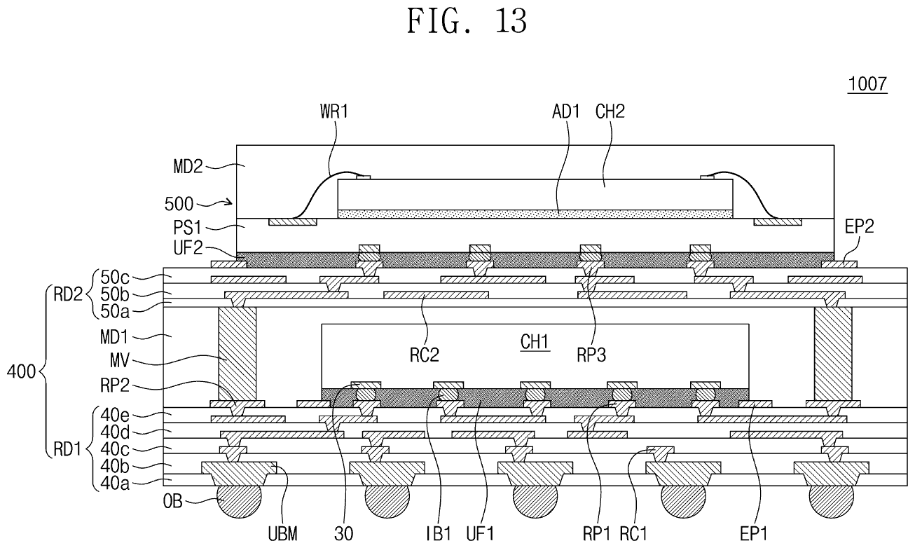

FIG. 13 illustrates a cross-sectional view showing a semiconductor package according to some embodiments of the present inventive concepts.

Referring to FIG. 13, a semiconductor package 1007 according to the present embodiment may have a package-on-package structure which includes a first sub-semiconductor package 400 and a second sub-semiconductor package 500 mounted on the first sub-semiconductor package 400. The first sub-semiconductor package 400 may have a structure identical or similar to that of the semiconductor package 1006 discussed with reference to FIG. 12. A second edge conductive pad EP2 may be disposed on the second substrate RD2 of the first sub-semiconductor package 400. The second edge conductive pad EP2 may be formed of the same material as that of the third conductive pads RP3, and may have their top surfaces located at the same height.

The second sub-semiconductor package 500 may be bonded through second inner connection members IB2 to the third conductive pads RP3 of the second substrate RD2 included in the first sub-semiconductor package 400. The second sub-semiconductor package 500 may include a first sub-package substrate PS1, a second semiconductor device CH2 disposed on the first sub-package substrate PS1, an adhesion layer AD1 interposed between the first sub-package substrate PS1 and the second semiconductor device CH2, a second mold layer MD2 that covers the first sub-package substrate PS1 and the second semiconductor device CH2, and first wires WR1 that connect the first sub-package substrate PS1 to the second semiconductor device CH2. The first sub-package substrate PS1 may be a double-sided or multi-layered printed circuit board. Alternatively, the first sub-package substrate PS1 may be a redistribution substrate. The second semiconductor device CH2 may be, for example, one selected from an image sensor chip such as CMOS image sensor (CIS), a microelectromechanical system (MEMS) device chip, an application specific integrated circuit (ASIC) chip, and a memory device chip such as Flash memory, DRAM, SRAM, EEPROM, PRAM, MRAM, ReRAM, HBM (high bandwidth memory), and HMC (hybrid memory cubic).

A second underfill layer UF2 may be interposed between the second sub-semiconductor package 500 and the first sub-semiconductor package 400. A portion of the second edge conductive pad EP2 may be covered with the second underfill layer UF2, and another portion of the second edge conductive pad EP2 may be exposed. A lateral surface of the second sub-semiconductor package 500 and a lateral surface of the second underfill layer UF2 may be aligned with each other (i.e., the lateral surface of the second sub-semiconductor package 500 and the lateral surface of the second underfill layer UF2 may be co-planar) and may overlap the second edge conductive pad EP2 (i.e., a plane defined by the lateral surface of the second sub-semiconductor package 500 and a plane defined by the lateral surface of the second underfill layer UF2 may intersect a surface of the second edge conductive pad EP2). Other configurations may be identical or similar to those of FIG. 12.

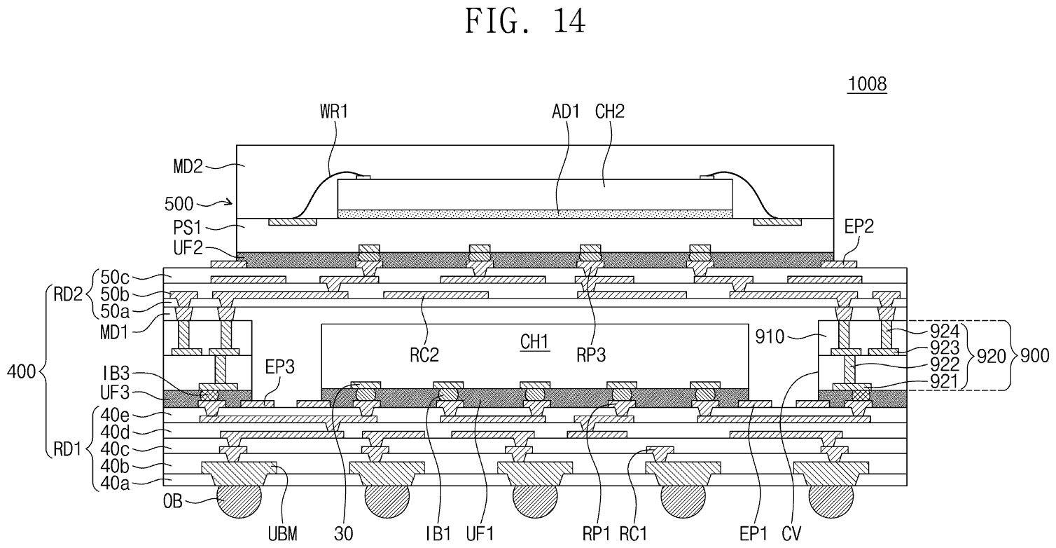

FIG. 14 illustrates a cross-sectional view showing a semiconductor package according to some embodiments of the present inventive concepts.

Referring to FIG. 14, a semiconductor package 1008 according to the present embodiment may include a connection substrate 900 in place of the mold vias MV in the structure of FIG. 13. The connection substrate 900 may include a cavity CV into which the first and second semiconductor devices CH1 and CH2 are inserted.

The connection substrate 900 may be connected through third inner connection members IB3 to the second conductive pads RP2 of the first redistribution substrate RD1. A third underfill layer UF3 may be interposed between the connection substrate 900 and the first redistribution substrate RD1.

The first redistribution substrate RD1 may further include a third edge conductive pad EP3 disposed on an upper portion thereof. A lateral surface of the third underfill layer UF3 may be aligned with an inner lateral surface of the cavity CV of the connection substrate 900 (i.e., the lateral surface of the third underfill layer UF3 and the inner lateral surface of the cavity CV of the connection substrate 900 may be co-planar), and may overlap the third edge conductive pad EP3 (i.e., a plane defined by the lateral surface of the third underfill layer UF3 and a plane defined by the inner lateral surface of the cavity CV of the connection substrate 900 may intersect a surface of the third edge conductive pad EP3).

The connection substrate 900 may include a plurality of base layers 910 and a conductive structure 920. The base layers 910 are illustrated formed of two layers in the present embodiment, but the present inventive concepts are not limited thereto and the base layers 910 may be formed of three or more layers. The base layers 910 may include a dielectric material. For example, the base layers 910 may include a carbon-based material, a ceramic, or a polymer.

The conductive structure 920 may include a connection pad 921, a first connection via 922, a first connection line 923, and a second connection via 924. In the present embodiment, the first connection via 922 and the first connection line 923 may be integrally formed into a single unitary piece. The conductive structure 920 may include metal, such as copper, aluminum, gold, nickel, or titanium. Other configurations may be the same as or similar to those discussed with reference to FIG. 13.

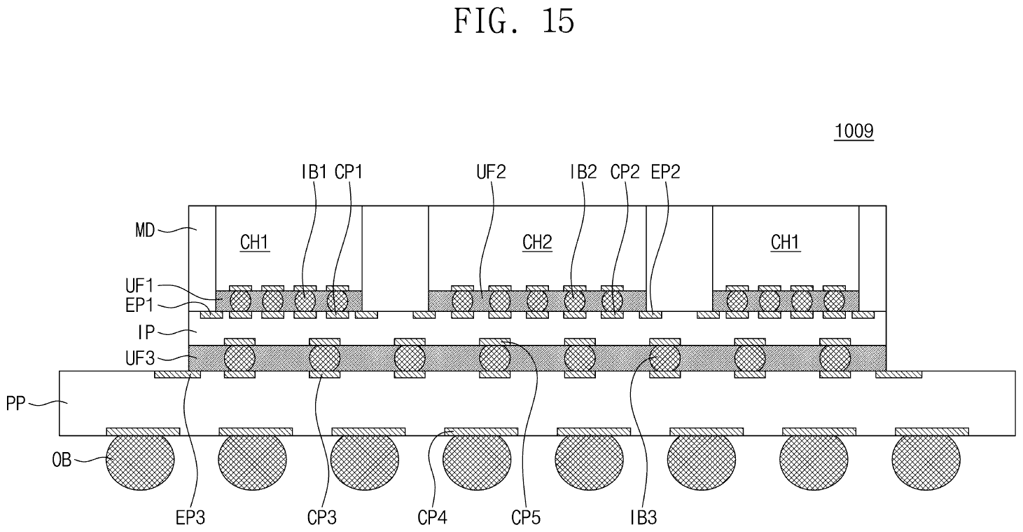

FIG. 15 illustrates a cross-sectional view showing a semiconductor package according to some embodiments of the present inventive concepts.

Referring to FIG. 15, a semiconductor package 1009 according to the present embodiment may include a first substrate PP. The first substrate PP may be, for example, a double-sided or multi-layered printed circuit board. The first substrate PP may be called a package substrate. The first substrate PP may include a first body layer, third conductive pads CP3 and third edge conductive pads EP3 disposed on a top surface of the first body layer, and fourth conductive pads CP4 disposed on a bottom surface of the first body layer. The first body layer may include a thermosetting resin such as an epoxy resin, a thermoplastic resin such as polyimide, a resin (e.g., prepreg) in which a thermosetting or thermoplastic resin is impregnated with a stiffener such as glass fiber and inorganic filler, or a photo-curable resin, but the present inventive concepts are not limited thereto. The third conductive pads CP3 and the third edge conductive pads EP3 may include the same material, and may have their top surfaces located at the same height. The fourth conductive pads CP4 may be provided with external connection terminals OB attached thereto.

A second substrate IP may be disposed on the first substrate PP. The second substrate IP may be called an interposer substrate. The second substrate IP may include first conductive pads CP1, second conductive pads CP2, a first edge conductive pad EP1, and a second edge conductive pad EP2 that are disposed on a top surface thereof. The second substrate IP may further include fifth conductive pads CP5 disposed on a bottom surface thereof. The first conductive pads CP1, the second conductive pads CP2, the first edge conductive pad EP1, and the second edge conductive pad EP2 may include the same material, and may have their top surfaces located at the same height. The second substrate IP may have a structure similar to that of the first semiconductor die 100 shown in FIG. 2. The second substrate IP may include a semiconductor substrate, interlayer dielectric layers, inner wiring lines, and through vias.

First semiconductor devices CH1 and a second semiconductor device CH2 may be mounted on the second substrate IP. The first semiconductor devices CH1 may be connected to the second semiconductor device CH2 through the inner wiring lines of the second substrate IP. The second semiconductor device CH2 may be, for example, a logic chip, a processor chip, or an application specific integrated circuit (ASIC) chip. The first semiconductor devices CH1 may each be a memory chip or a high bandwidth memory (HBM) chip. A mold layer MD may fill a space between the first semiconductor devices CH1 and the second semiconductor device CH2.

First inner connection members IB1 may connect the first semiconductor devices CH1 to the second substrate IP. Second inner connection members IB2 may connect the second semiconductor devices CH1 to the second substrate IP. Third inner connection members IB3 may connect the second substrate IP to the first substrate PP.

A first underfill layer UF1 may be interposed between the first semiconductor device CH1 and the second substrate IP. A second underfill layer UF2 may be interposed between the second semiconductor device CH2 and the second substrate IP. A third underfill layer UF3 may be interposed between the second substrate IP and the first substrate PP.

A lateral surface of the first semiconductor device CH1 may be aligned with a lateral surface of the first underfill layer UF1 (i.e., the lateral surface of the first semiconductor device CH1 and the lateral surface of the first underfill layer UF1 may be co-planar), and may overlap the first edge conductive pad EP1 (i.e., a plane defined by the lateral surface of the first semiconductor device CH1 and a plane defined by the lateral surface of the first underfill layer UF1 may intersect a surface of the first edge conductive pad EP1). A lateral surface of the second semiconductor device CH2 may be aligned with a lateral surface of the second underfill layer UF2 (i.e., the lateral surface of the second semiconductor device CH2 and the lateral surface of the second underfill layer UF2 may be co-planar), and may overlap the second edge conductive pad EP2 (i.e., a plane defined by the lateral surface of the second semiconductor device CH2 and a plane defined by the lateral surface of the second underfill layer UF2 may intersect a surface of the second edge conductive pad EP2). A lateral surface of the second substrate IP may be aligned with a lateral surface of the third underfill layer UF3 (i.e., the lateral surface of the second substrate IP and the lateral surface of the third underfill layer UF3 may be co-planar), and may overlap the third edge conductive pad EP3 (i.e., a plane defined by the lateral surface of the second substrate IP and a plane defined by the lateral surface of the third underfill layer UF3 may intersect a surface of the third edge conductive pad EP3). Other configurations may be identical or similar to those discussed above.

In a semiconductor package according to the present embodiments, a fillet part of an underfill layer may be removed, and thus it may be possible to prevent or minimize delamination between a mold layer and semiconductor dies. As a result, the semiconductor package may have improved reliability.

In a method of fabricating a semiconductor package according to the present inventive concepts, a laser may be used to remove a fillet part of an underfill layer, and an edge conductive pad may be used to prevent semiconductor dies from damage. As a result, process failure may be reduced to increase a yield.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts. The embodiments of FIGS. 1 to 15 may be combined with each other.

1. A semiconductor package, comprising:
a first semiconductor die;
a second semiconductor die on the first semiconductor die;
an underfill layer between the first semiconductor die and the second semiconductor die; and
a mold layer on a top surface of the first semiconductor die and a lateral surface of the second semiconductor die,
wherein the first semiconductor die comprises:
a first semiconductor substrate; and
an edge conductive pad on a rear surface of the first semiconductor substrate,
wherein one portion of the edge conductive pad and the second semiconductor die overlap, and
wherein another portion of the edge conductive pad is covered by the mold layer.

2. The semiconductor package of claim 1, wherein the one portion of the edge conductive pad is in contact with the underfill layer.

3. The semiconductor package of claim 1, wherein, in plan view, the edge conductive pad has a tetragonal ring shape that extends around the second semiconductor die.

4. The semiconductor package of claim 1, wherein the edge conductive pad comprises a plurality of edge conductive pads that extend around the second semiconductor die in plan view.

5. The semiconductor package of claim 4, further comprising a residual underfill pattern between the plurality of edge conductive pads.

6. The semiconductor package of claim 1, wherein a lateral surface of the underfill layer is co-planar with the lateral surface of the second semiconductor die.

7. The semiconductor package of claim 1,
wherein the first semiconductor die further comprises a first conductive pad on a rear surface of the first semiconductor substrate and spaced apart from the edge conductive pad,
wherein the second semiconductor die comprises:
a second conductive pad on a bottom surface of the second semiconductor die and connected to the first conductive pad; and
a solder layer between the second conductive pad and the first conductive pad,
wherein a top surface of the first conductive pad is at a first height from the rear surface of the first semiconductor substrate,
wherein a top surface of the edge conductive pad is at a second height from the rear surface of the first semiconductor substrate, and
wherein the second height is about 0.9 times to about 1.1 times the first height.

8. The semiconductor package of claim 7, wherein the edge conductive pad and the first conductive pad comprise the same material.

9. The semiconductor package of claim 7, wherein
the first conductive pad has a first width in a first direction, and
the edge conductive pad has a width in the first direction greater than the first width.

10. The semiconductor package of claim 7, further comprising:
a first through via that contacts the first conductive pad and penetrates the first semiconductor substrate; and
an edge through via that contacts the edge conductive pad and penetrates the first semiconductor substrate,
wherein a width of the edge through via is the same as or greater than a width of the first through via.

11. The semiconductor package of claim 1, wherein
the underfill layer is on the lateral surface of the second semiconductor die, and
wherein a thickness of the underfill layer is in a range of about 0 μm to about 50 μm on the lateral surface of the second semiconductor die.

12. The semiconductor package of claim 1, further comprising:
a plurality of third semiconductor dies sequentially stacked on the second semiconductor die; and
a plurality of second underfill layers, wherein a respective one of the plurality of second underfill layers is between adjacent ones of the plurality of third semiconductor dies,
wherein the mold layer is on lateral surfaces of the plurality of third semiconductor dies and lateral surfaces of the plurality of second underfill layers, and
wherein the lateral surfaces of the plurality of second underfill layers are co-planar with the lateral surfaces of the plurality of third semiconductor dies.

13. A semiconductor package, comprising:
a first semiconductor die;
a second semiconductor die on the first semiconductor die;
an underfill layer between the first semiconductor die and the second semiconductor die; and
a mold layer on a top surface of the first semiconductor die and a lateral surface of the second semiconductor die,
wherein the first semiconductor die comprises:
a first semiconductor substrate; and
an edge conductive pad and a first conductive pad on a rear surface of the first semiconductor substrate,
wherein the edge conductive pad and a lateral surface of the second semiconductor die overlap, and
wherein the edge conductive pad and the first conductive pad comprise the same material.

14. The semiconductor package of claim 13, wherein
a first portion of the edge conductive pad is in contact with the underfill layer, and
a second portion of the edge conductive pad is in contact with the mold layer.

15. The semiconductor package of claim 13, wherein the edge conductive pad comprises a plurality of edge conductive pads that extend around the second semiconductor die in plan view.

16. The semiconductor package of claim 15, further comprising a residual underfill pattern between the plurality of edge conductive pads.

17. A semiconductor package, comprising:
a buffer die;
a plurality of memory dies sequentially stacked on the buffer die;
a first underfill layer between the buffer die and a lowermost one of the plurality of memory dies;
a plurality of second underfill layers, wherein a respective one of the plurality of second underfill layers is between adjacent ones of the plurality of memory dies; and
a mold layer on a top surface of the buffer die, lateral surfaces of the plurality of memory dies, a lateral surface of the first underfill layer, and lateral surfaces of the plurality of second underfill layers,
wherein the buffer die comprises:
a first semiconductor substrate;
a first interlayer dielectric layer on a front surface of the first semiconductor substrate;
a plurality of first wiring lines in the first interlayer dielectric layer;
a first backside dielectric layer on a rear surface of the first semiconductor substrate;
an edge conductive pad and a first conductive pad on the first backside dielectric layer; and
a first through via that penetrates the first backside dielectric layer, the first semiconductor substrate, and a portion of the first interlayer dielectric layer to contact the first conductive pad,
wherein the first conductive pad and the plurality of memory dies overlap,
wherein a portion of the edge conductive pad is in contact with the mold layer,
wherein a top surface of the first conductive pad is at a first height from the rear surface of the first semiconductor substrate,
wherein a top surface of the edge conductive pad is at a second height from the rear surface of the first semiconductor substrate, and
wherein the second height is about 0.9 times to about 1.1 times the first height.

18. The semiconductor package of claim 17, wherein
the first underfill layer and the plurality of second underfill layers are on the lateral surfaces of the plurality of memory dies, and
a thickness of at least one selected from the first underfill layer and the plurality of second underfill layers is in a range of about 0 μm to about 50 μm on the lateral surfaces of the plurality of memory dies.

19. The semiconductor package of claim 17, wherein the edge conductive pad and the lateral surfaces of the plurality of memory dies overlap.

20. The semiconductor package of claim 17, wherein
the edge conductive pad and the first conductive pad comprise the same material,
the first conductive pad has a first width in a first direction, and
the edge conductive pad has a width in the first direction greater than the first width.

21-23. (canceled)
